(19) United States
(12) Patent Application Publication
(10) Pub. No.: US 2025/0133842 A1
(43) Pub. Date: Apr. 24, 2025

(54) IMAGE SENSOR AND IMAGE SENSING DEVICE INCLUDING THE SAME

(71) Applicant: SAMSUNG ELECTRONICS CO., LTD., Suwon-si (KR)

(72) Inventors: Jung Wook LIM, Suwon-si (KR); Sung Hyuck CHO, Suwon-si (KR)

(73) Assignee: SAMSUNG ELECTRONICS CO., LTD., Suwon-si (KR)

(21) Appl. No.: 18/754,976

(22) Filed: Jun. 26, 2024

(30) Foreign Application Priority Data
Oct. 23, 2023 (KR) 10-2023-0142081

(51) Int. Cl. H01L 27/146

(52) U.S. Cl. CPC H10F 39/8027

(57) ABSTRACT

An image sensor includes a pixel array including a plurality of unit pixels and a driving circuitry provided around the pixel array and driving the plurality of unit pixels. Each of the plurality of unit pixels includes a first region ad a second region. The first region includes a first photodiode, a first transfer transistor connected to the first photodiode, a first floating diffusion node connected to the first transfer transistor, and a (1-1)-th contact connected to a second floating diffusion node, and the second region includes a second photodiode, a second transfer transistor connected to the second photodiode, a (1-2)-th contact electrically connected to the (1-1)-th contact through connection metal wiring, and a second contact provided to a third floating diffusion node connected to the second transfer transistor.

### CROSS-REFERENCE TO RELATED APPLICATION

This application is based on and claims priority under 35 U.S.C. § 119 to Korean Patent Application No. 10-2023-0142081, filed on Oct. 23, 2023, in the Korean Intellectual Property Office, the disclosure of which is incorporated by reference herein in its entirety.

### BACKGROUND

### 1. Field

The disclosure relates to an image sensing device including an image sensor.

### 2. Description of the Related Art

An image sensing device is a type of semiconductor device that converts optical information (e.g., incident light) into electrical signals. Examples of the image sensing device include a charge-coupled device (CCD) image sensing device and a complementary metal-oxide semiconductor (CMOS) image sensing device.

A CMOS image sensor (CIS) includes a two-dimensional (2D) array of multiple pixels. Each of the pixels may include, for example, a photodiode (PD), which converts incident light into an electrical signal.

Recently, with the development of the computer and telecommunications industries, the demand for image sensors with improved performance has been increasing in various fields, including the fields of digital cameras, camcorders, smartphones, gaming devices, surveillance cameras, medical micro cameras, robots, vehicles, etc.

### SUMMARY

Aspects of the disclosure provide an image sensor with an improved dark signal non-uniformity (DSNU) in a high-dynamic range (HDR) environment, and an image sensing device with an enhanced image quality.

Aspects of the disclosure also provide a vehicle or a mobile device including an image sensor with an improved DSNU in an HDR environment.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, there is provided an image sensor including: a pixel array including a plurality of unit pixels; and a driving circuitry configured to drive the plurality of unit pixels, wherein each of the plurality of unit pixels includes: a first region including a first photodiode, a first transfer transistor connected to the first photodiode, a first floating diffusion node connected to the first transfer transistor, and a first contact connected to a second floating diffusion node, and a second region including a second photodiode, a second transfer transistor connected to the second photodiode, a second contact electrically connected to the first contact through a metal wiring connection, and a third contact provided to a third floating diffusion node connected to the second transfer transistor.

According to another aspect of the disclosure, there is provided an image sensor including a pixel array including a plurality of unit pixels; and a driving circuitry configured to drive the plurality of unit pixels, wherein each of the plurality of unit pixels includes: a first region including a first photodiode, a first transfer transistor connected to the first photodiode, a first floating diffusion node connected to the first transfer transistor, a first contact connected to a second floating diffusion node, and a second contact, and a second region including a second photodiode, a second transfer transistor connected to the second photodiode, and a third contact connected to a third floating diffusion node together with the second contact.

According to another aspect of the disclosure, there is provided an image sensing device including: a pixel array including a plurality of unit pixels; and a driving circuitry configured to drive the plurality of unit pixels, wherein each of the plurality of unit pixels includes: a first transfer transistor connected between a first photodiode and a first floating diffusion node, a photodiode switching transistor connected between the first floating diffusion node and a second floating diffusion node, the photodiode switching transistor configured to turn on based on a photodiode switching control signal, a second transfer transistor connected between a second photodiode and a third floating diffusion node, a metal capacitor connected between the third floating diffusion node and a fourth floating diffusion node, and a first connection transistor connected between the fourth floating diffusion node and a first power supply line, the first connection transistor configured to turn on based on a capacitor connection control signal.

It should be noted that the effects of the disclosure are not limited to those described above, and other effects of the disclosure will be apparent from the following description.

### BRIEF DESCRIPTION OF DRAWINGS

The above and other aspects and features of the disclosure will become more apparent by describing in detail exemplary embodiments thereof with reference to the attached drawings, in which:

FIG. 1 is a block diagram of an image sensing device according to an embodiment of the disclosure.

FIG. 2 is a top view of a pixel array according to an embodiment of the disclosure.

FIG. 3 is a pixel diagram of a unit pixel according to an embodiment of the disclosure.

FIG. 4 is a signal diagram illustrating an operation of the unit pixel of FIG. 3.

FIG. 5 is a circuit diagram of a unit pixel according to an embodiment of the disclosure.

FIG. 6 is a diagram illustrating a layout of the unit pixel of FIG. 5.

FIG. 7 is a layout view of the unit pixel of FIG. 6.

FIG. 8 is a circuit diagram of a unit pixel according to an embodiment.

FIG. 9 is a diagram illustrating a layout of the unit pixel of FIG. 8.

FIG. 10 is a layout view of the unit pixel of FIG. 9.

FIG. 11 is a schematic diagram of a vehicle including an image sensor according to an embodiment of the disclosure.

### DETAILED DESCRIPTION

Embodiments of the disclosure will be described with reference to the attached drawings.

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component is described as being “connected to,” or “coupled to” another component, it may be directly “connected to,” or “coupled to” the other component, or there may be one or more other components intervening therebetween. In contrast, when an element is described as being “directly connected to,” or “directly coupled to” another element, there can be no other elements intervening therebetween. Likewise, similar expressions, for example, “between” and “immediately between,” and “adjacent to” and “immediately adjacent to,” are also to be construed in the same way. As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment (e.g., as to what an example or embodiment may include or implement) means that at least one example or embodiment exists where such a feature is included or implemented, while all example embodiments are not limited thereto.

The embodiments of the disclosure are example embodiments, and thus, the disclosure is not limited thereto and may be realized in various other forms. As is traditional in the field, embodiments may be described and illustrated in terms of blocks, as shown in the drawings, which carry out a described function or functions. These blocks, which may be referred to herein as units or modules or the like, or by names such as device, logic, circuit, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like, and may be implemented by or driven by software and/or firmware (configured to perform the functions or operations described herein).

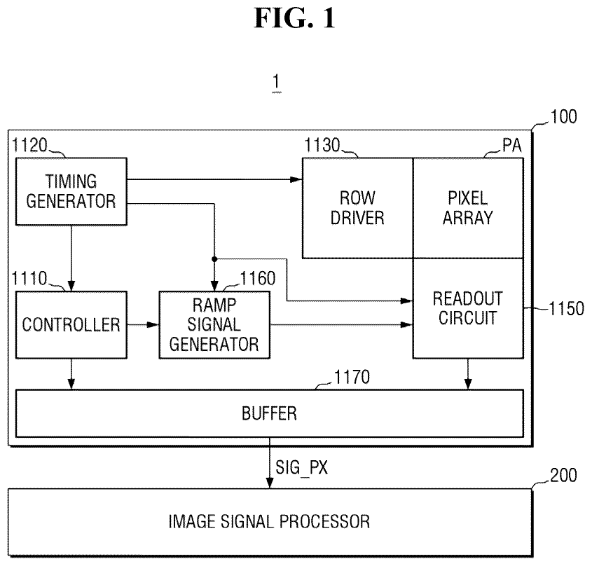

FIG. 1 is a block diagram of an image sensing device according to an embodiment of the disclosure.

Referring to FIG. 1, an image sensing device 1 may include an image sensor 100 and an image signal processor 200. However, the disclosure is not limited thereto, and as such, the image sensing device 1 may include one or more other components.

According to an embodiment, the image sensor may include a controller 1110, a timing generator 1120, a row driver 1130, a readout circuit 1150, a ramp signal generator 1160, and a buffer 1170. However, the disclosure is not limited thereto, and as such, according to another embodiment, one or more components illustrated in FIG. 1 may be combined or deleted. Moreover, according to another embodiment, one or more components may be added to the components illustrated in FIG. 1. The image sensor 100 may generate a pixel signal SIG_PX based on an incident light on the image sensor 100. For example, the image sensor 100 may generate a pixel signal SIG_PX by sensing an image of a sensing target using light. In an embodiment, the pixel signal SIG_PX may be, for example, a digital signal, but the disclosure is not limited thereto. The pixel signal SIG_PX may also include a particular signal voltage or reset voltage.

The pixel signal SIG_PX may be provided to the image signal processor 200. For example, the pixel signal SIG_PX may be provided to the image signal processor 200 to be processed by the image signal processor 200. The image signal processor 200 may receive the pixel signal SIG_PX output from a buffer 1170 of the image sensor 100, and may process or manipulate the pixel signal SIG_PX for display convenience.

In an embodiment, the image signal processor 200 may perform digital binning on the pixel signal SIG_PX output from the image sensor 100. In this case, the pixel signal SIG_PX output from the image sensor 100 may be either a raw image signal from a pixel array PA that is yet to be subject to analog binning, or a pixel signal SIG_PX that has already undergone analog binning.

In an embodiment, the image sensor 100 and the image signal processor 200 may be arranged separately from each other. For example, the image sensor 100 may be mounted on a first chip, and the image signal processor 200 may be mounted on a second chip and communicate with the image sensor 100 through a predetermined interface. However, the disclosure is not limited to this example. Alternatively, the image sensor 100 and image signal processor 200 may be implemented as a single package, such as a multi-chip package (MCP).

The image sensor 100 includes the pixel array PA and a driver circuit. The driver circuit is provided adjacent to the pixel array PA. For example, the driver circuit may be provided around the pixel array PA. The driver circuit may be configured to drive the pixel array PA in units of unit pixels. According to an embodiment, the driver circuit may include, for example, the controller 1110, a timing generator 1120, a row driver 1130, a readout circuit 1150, a ramp signal generator 1160, and the buffer 1170.

The controller 1110 may control the overall operation of the image sensor 100. For example, the controller 1110 may transmit operating signals directly to the timing generator 1120, the ramp signal generator 1160, and the buffer 1170. According to an embodiment, the controller 1110 may be referred to as a control register block or a controller circuit.

The timing generator 1120 may generate signals that serve as a reference for the operating timings of various components of the image sensor 100. The signals generated by the timing generator 1120 may be transmitted to the row driver 1130, the readout circuit 1150, and the ramp signal generator 1160. According to an embodiment, the timing generator 1120 may be referred to as a timing generator circuit.

The ramp signal generator 1160 may generate and transmit ramp signals for use in the readout circuit 1150. For example, the readout circuit 1150 may include a correlated double sampler (CDS) and a comparator, and the ramp signal generator 1160 may generate and transmit ramp signals for use in the CDS and the comparator. According to an embodiment, the ramp signal generator 1160 may be referred to as a ramp signal circuit.

The buffer 1170 may include, for example, a latch. The buffer 1170 may temporarily store the pixel signal SIG_PX to be provided externally and may transmit the pixel signal SIG_PX to an external memory or device. The buffer 1170 may include a memory such as a dynamic random-access memory (DRAM) or static random-access memory (SRAM).

The pixel array PA may sense an external image. The pixel array PA may include a plurality of pixels (or unit pixels). The row driver 1130 may selectively activate rows of the pixel array PA.

The readout circuit 1150 may sample pixel signals provided from the pixel array PA, compare the sampled pixel signals with a ramp signal, and may convert an analog image signal (or analog image data) into a digital image signal (or digital image data) based on the results of the comparison.

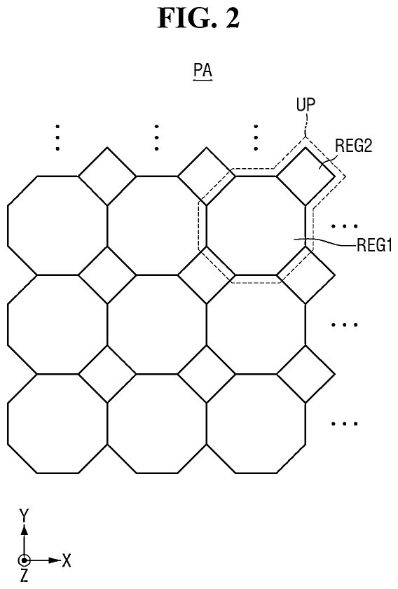

FIG. 2 is a top view of a pixel array according to an embodiment of the disclosure.

Referring to FIG. 2, the pixel array PA may include a plurality of unit pixels UP. For example, the plurality of unit pixels UP may be arranged in first and second directions X and Y. For example, the plurality of unit pixels UP may be regularly or repeatedly arranged in first and second directions X and Y. Here, the plurality of unit pixels UP may be units that receive light and output an image corresponding to one pixel.

According to some example cases, high dynamic range (HDR) of at least 120 dB to 140 dB may be necessary. For example, image sensors for automotive use may require such HDR. In order to meet such HDR, the image sensor 100 may be implemented with unit pixels UP containing different types of photodiodes. For example, each unit pixel UP may include at least one large photodiode and at least one small photodiode. Each unit pixel UP may include a first region REG1 corresponding to the large photodiode and a second region REG2 corresponding to the small photodiode. The first regions REG1 and the second regions REG2 may be distinguished from in a top view. The first regions REG1 may be in the shape of a first polygon such as, for example, an octagon, and the second regions REG2 may be in the shape of a second polygon such as, for example, a quadrilateral. However, the disclosure is not limited, and as such, the first regions REG1 and the second regions REG2 may have other shapes. The first regions REG1 and the second regions REG2 may contact one another. The first regions REG1 and the second regions REG2 have different sensitivities. For example, the second regions REG2 may have a relatively small sensitivity, and the first regions REG1 may have a larger sensitivity than the second regions REG2.

According to an embodiment, the first regions REG1 and the second regions REG2 may be different sizes. For example, the first regions REG1 may be larger than the second regions REG2. That is, the amount of light incident on the first regions REG1 may be greater than the amount of light incident on the second regions REG2. Each of the plurality of unit pixels UP, including the first regions REG1 and the second regions REG2, may convert light into electrical signals.

In an example case in which HDR is implemented by adjusting exposure time in the image sensor 100, problems such as light-emitting diode (LED) flicker mitigation arise. Since LED light sources, which are used in vehicles and road traffic, operate at frequencies over 90 Hz and involve numerous flicker frequencies, the image sensor 100 prevents loss that may be caused by flicker components in actual measured signals by setting an effective integration time (EIT) to be longer than the flicker cycle of the LED light sources. Thus, the image sensor 100 can be less affected by flicker events while implementing HDR performance because it includes large photodiodes with a higher sensitivity in the first regions REG1 and small photodiodes with a lower sensitivity in the second regions REG2. In addition, since the image sensor 100 further includes metal capacitors to store overflown charges from the small photodiodes, the HDR performance of the image sensor 100 can be enhanced. However, in an example case in which signals are read from the metal capacitors, charge domain sampling (CDS) is not possible, which may lead to leakage current in switch transistors for the metal capacitors. As the EIT increases, the leakage current between the metal capacitors and the switch transistors may increase, which may lead to deterioration of dark signal non-uniformity (DSNU) and decreases in signal-to-noise ratio (SNR).

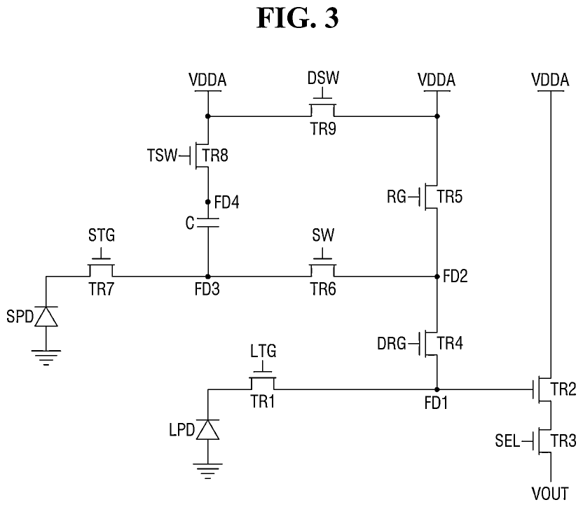

FIG. 3 is a pixel diagram of a unit pixel according to an embodiment of the disclosure.

Referring to FIGS. 2 and 3, the pixel circuit of a unit pixel UP in the pixel array PA includes a first photodiode LPD, a second photodiode SPD, a plurality of transistors, and a metal capacitor C. The plurality of transistors may include a first transfer transistor TR1, a second transfer transistor TR7, a source follower transistor TR2, a selection transistor TR3, a reset transistor TR5, a connection transistor TR6, a photodiode switching transistor TR4, and a capacitor connection transistor TR8. According to an embodiment, a first transfer signal LTG may be applied to the first transfer transistor TR1, and a second transfer signal STG may be applied to the second transfer transistor TR7.

A first subpixel REG1 includes the first photodiode LPD and the first transfer transistor TR1, and a second subpixel REG2 may include the second photodiode SPD and the second transfer transistor TR7. The first photodiode LPD corresponds to the first regions REG1 of FIG. 2, and the second photodiode SPD corresponds to the second regions REG2 of FIG. 2. The first photodiode LPD, which includes a relatively large first region REG1 in the plan view of FIG. 2, may be referred to as a large photodiode, and the second photodiode SPD, which includes a relatively small second region REG2 in the plan view of FIG. 2, may be referred to as a small photodiode. For example, the first photodiode LPD may be larger than the second photodiode SPD.

The first and second subpixels REG1 and REG2 may share the source-follower transistor TR2, the selection transistor TR3, and the reset transistor TR5.

For example, the first transfer transistor TR1 may be provided between the first photodiode LPD and a first node FD1. The first node FD1 may be connected to a first floating diffusion region FD1 or the first node FD1 may be itself a first floating diffusion region FD1. The gate of the first transfer transistor TR1 is connected to a first transfer line to receive the first transfer signal LTG.

The source-follower transistor TR2 may be connected between a first power supply line VDDA, which provides a first power voltage, and an output signal line VOUT. The gate of the source-follower transistor TR2 may be connected to the first node FD1.

The selection transistor TR3 may be provided between the source-follower transistor TR2 and the output signal line VOUT. The gate of the selection transistor TR3 may be connected to a selection line of a corresponding row to receive a selection signal SEL.

The photodiode switching transistor TR4 and the reset transistor TR5 may be provided between the first node FD1 and the first power supply line VDDA, which provides the first power voltage. The common node between the photodiode switching transistor TR4 and the reset transistor TR5 is defined as a second node FD2. The photodiode switching transistor TR4 may be positioned between the first node FD1 and the second node FD2. The gate of the photodiode switching transistor TR4 may be connected to a connection signal line. The photodiode switching transistor TR4 may connect the first node FD1 to the second node FD2 according to a photodiode switching control signal DRG provided from the connection signal line. The reset transistor TR5 may be provided between the first power supply line VDDA and the second node FD2. The gate of the reset transistor TR5 may be connected to a reset line to receive a reset signal RG.

The second transfer transistor TR7 and the connection transistor TR6 may be provided between the second photodiode SPD and the second node FD2. The common node between the second transfer transistor TR7 and the connection transistor TR6 may be defined as a third node FD3. The second transfer transistor TR7 is connected between the second photodiode SPD and the third node FD3. The third node FD3 may be connected to the second node FD2. The gate of the second transfer transistor TR7 may be connected to a second transfer line. The second transfer line applies the second transfer signal STG, which is a different scan signal from the first transfer signal LTG from the first transfer line, and accordingly, the first and second transfer transistors TR1 and TR7 may be turned on and off at different times. For example, the first and second transfer transistors TR1 and TR7 may be turned on and off independently or separate from each other. However, the disclosure is not limited thereto, and as such, the first and second transfer transistors TR1 and TR7 may be turned on and off at the same time.

The connection transistor TR6 may be provided between the third node FD3 and the second node FD2. The gate of the connection transistor TR6 is connected to a switch control line. The connection transistor TR6 may connect the third node FD3 and the second node FD2 according to a connection control signal SW.

In an embodiment, the metal capacitor C may be provided between the third node FD3 and a fourth node FD4. The capacitor connection transistor TR8 may be connected between the fourth node FD4 and the first power supply line VDDA. The capacitor connection transistor TR8 may store the overflown charge from the second photodiode SPD in the metal capacitor C according to a capacitor connection signal TSW. However, the disclosure is not limited thereto, and as such according to some cases, the capacitor connection transistor TR8 may not store the overflown charge from the second photodiode SPD in the metal capacitor C according to the capacitor connection signal TSW.

In an embodiment, a power connection transistor TR9 may be further included to connect the common node between the first power supply line VDDA and the capacitor connection transistor TR8 and the common node between the first power supply line VDDA and the reset transistor TR5 according to a power connection signal DSW.

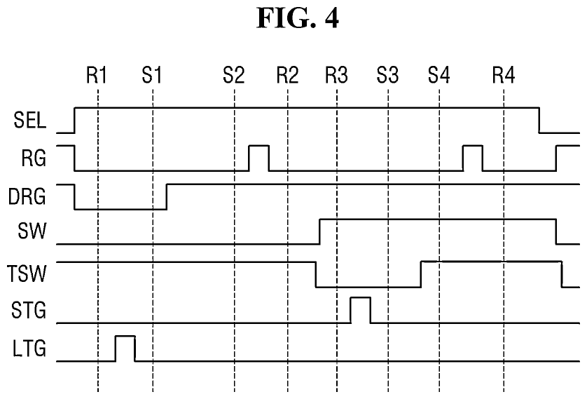

FIG. 4 is a signal diagram illustrating an operation of the unit pixel of FIG. 3.

FIG. 4 illustrates the timings of signals applied to a unit pixel UP located in a row to be read out. However, the disclosure is not limited thereto, and as such, different signals from those illustrated in FIG. 4 may be applied to unit pixels UP in a row not selected as a target to be read out. For example, signal waveforms preceding or following those illustrated in FIG. 4 may be applied to unit pixels UP from a row not selected as a target to be read out.

According to an embodiment, FIG. 4 shows the waveforms of the selection signal SEL, the reset signal RG, the photodiode switching control signal DRG, the connection control signal SW, the capacitor connection signal TSW, the second transfer signal STG, and the first transfer signal LTG. Each of the signal waveforms may swing between high-level and low-level voltages. According to an embodiment illustrated in FIG. 4, the high-level voltage activates each applied transistor as a turn-on signal, and the low-level voltage deactivates each applied transistor as a turn-off signal. However, the disclosure is not limited thereto, and as such, according to another embodiment, each transistor may be turned off by the high-level voltage and turned on by the low-level voltage.

Before a readout period, the reset signal RG, the photodiode switching control signal DRG, and the capacitor connection signal TSW maintain a high level, while the connection control signal SW, the second transfer signal STG, and the first transfer signal LTG maintain the low level. For example, before the readout period, the selection signal SEL may be at a low level.

During a period from point R1 to point S1, which corresponds to a first operation phase, as the selection signal SEL transitions to the high level, the reset signal RG and the photodiode switching control signal DRG transition from the high level to the low level, performing a reset operation, and the charge accumulated at the first node FD1 is converted into a first reset voltage through the source-follower transistor TR2 and output to the output signal line VOUT. In the first operation phase, the first transfer signal LTG toggles from the low level to the high level to the low level. While the first transfer signal LTG maintains the high level, the first transfer transistor TR1 may be turned on for a predetermined amount of time and may then turned off. While the first transfer transistor TR1 is turned on, the first node FD1 may be connected to the first photodiode LPD. As a result, the charge stored in the first photodiode LPD may be transferred to the first node (or first floating diffusion region) FD1. The charge transferred to the first node (or first floating diffusion region) FD1 may be converted into a first signal voltage VS1 by the source-follower transistor TR2 and output to the output signal line VOUT.

In a second operation phase following the first operation phase, a second signal operation S2 may be performed first, and then, a second reset operation R2 may be performed. The photodiode switching control signal DRG switches from the low level to the high level at point S2, turning on the photodiode switching transistor TR4 to connect the first node FD1 to the second node FD2. After point S2, the reset signal RG toggles from the low level to the high level to the low level, performing the second reset operation at point R2. The second reset operation resets both the first node FD1 and the second node FD2 that are connected, converting the charge into a second reset voltage VS2 through the source-follower transistor TR2 and outputting the second reset voltage VS2 to the output signal line VOUT.

In a third operation phase following the second operation phase, a third reset operation R3 may be performed first, and then, a third signal operation S3 may be performed. During a period between points R2 and R3, the connection control signal SW transitions from the low level to the high level, turning on the connection transistor TR6, while the capacitor connection signal TSW transitions from the high level to the low level, turning off the capacitor switch transistor TR8. As a result, the second node FD2, the third node FD3, and the fourth node FD4 are connected together, and the fourth node FD4 is disconnected from the first power supply line VDDA.

During a period from point R3 to point S3, the second transfer signal STG toggles from the low level to the high level to the low level. The connection control signal SW maintains the high level, and the capacitor connection signal TSW maintains the low level. While the second transfer signal STG maintains the high level, the second transfer transistor TR7 may be turned on for a predetermined amount of time and may then be turned off. While the second transfer transistor TR7 is on, the third node FD3 may be connected to the second photodiode SPD. As a result, the charge stored in the second photodiode SPD is transferred to the floating diffusion region of the third node FD3, the charge stored in the third node FD3 may be transferred to the second node FD2 connected to the third node FD3 through the turned-on connection transistor TR6, and the charge transferred to the second node FD2 may be transmitted to the first node FD1 through the turned on switching transistor TR4. The charge at the first node FD1 may be converted into a third signal voltage VS3 by the source-follower transistor TR2 and may then be output. The third signal voltage VS3 does not include output of the charge accumulated in the metal capacitor C while the capacitor connection transistor TR8 is off. Also, since the capacitor connection transistor TR8, connected between the first power supply line VDDA and the fourth node FD4, is turned off by the capacitor connection signal TSW, there may be no leakage current to the first power supply line VDDA or the power connection transistor TR9 from the charge accumulated in the metal capacitor C.

In a fourth operation phase following the third operation, a fourth signal operation S4 may be performed first, and then, a fourth reset operation R4 may be performed. During a period from point S3 to point S4, the capacitor connection signal TSW may switch from the low level to the high level. Accordingly, the metal capacitor C is connected to the third node FD3, and the overflown charge from the third node FD3 is accumulated in the metal capacitor C. As a result of the turning on of the connection transistor TR6 and the switching transistor TR4, the first node FD1, the second node FD2, and the third node FD3 may all be connected together, and the accumulated charge in the first node FD1, the second node FD2, the third node FD3 and the metal capacitor C may be converted into a fourth signal voltage VS4 by the source-follower transistor TR2 and may then be output.

During a period from point S4 to point R4, the reset signal RG toggles from the low level to the high level to the low level, while the connection control signal SW, the photodiode switching control signal DRG, and the capacitor connection signal TSW maintain the high level. As the connection transistor TR6, the capacitor connection transistor TR8, and the switching transistor TR4 are turned on by the connection control signal SW, the photodiode switching control signal DRG, and the capacitor connection signal TSW, the first node FD1, the second node FD2, the third node FD3 and the fourth node FD4 are connected. While the reset transistor TR5 is turned on, the first node FD1, the second node FD2, the third node FD3 and the fourth node FD4 may be reset based on the first power supply line VDDA, and the charge accumulated in the first node FD1, the second node FD2, the third node FD3 and the fourth node FD4 may be converted into, and output as, a fifth signal voltage VS5 by the source-follower transistor TR2.

After the fourth operation phase or point R4, the selection signal SEL switches from the high level to the low level, deactivating the unit pixel UP.

In short, the first operation phase may include outputting the charge generated by the first photodiode LPD as a first output signal VS1, the second operation phase may include turning on the reset transistor TR5 to reset the residual charge accumulated at the first node FD1 and the second node FD2 and output it as a second output signal VS2, and the third operation phase may include outputting the charge generated by the second photodiode SPD as a third output signal VS3. Moreover, the fourth operation phase may include storing the charge generated by the second photodiode SPD but overflown from the third node FD3 in the metal capacitor C and outputting the stored overflown charge as a fourth output signal VS4, and the fifth operation phase may include resetting the residual charge in the first, second, third, and fourth nodes FD1, FD2, FD3, FD4 and the metal capacitor C upon the completion of the first, second, third, and fourth operation phases and outputting it as a fifth output signal VS5.

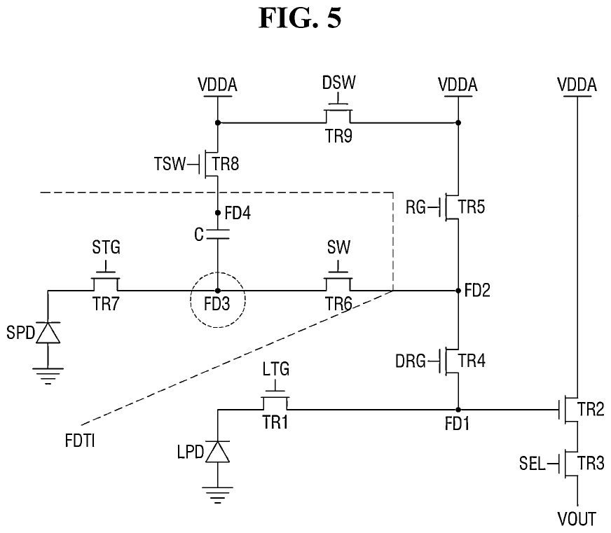

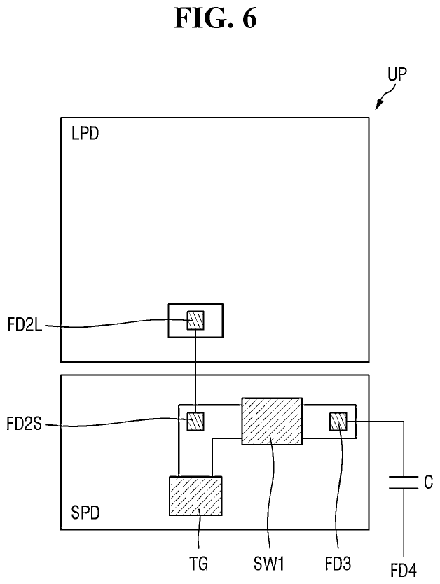

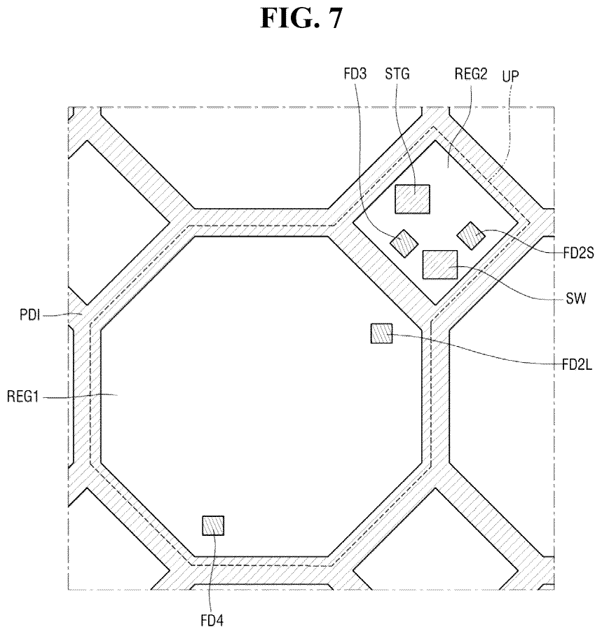

FIG. 5 is a circuit diagram of a unit pixel according to an embodiment of the disclosure, FIG. 6 is a diagram illustrating a layout of the unit pixel of FIG. 5, and FIG. 7 is a layout view of the unit pixel of FIG. 6.

In an embodiment, first and second photodiodes LPD and SPD of a unit pixel UP may be connected to a second node FD2. As a result, a third node FD3 may be implemented with a single contact.

Referring to FIGS. 5 and 6, the first photodiode LPD, a first transfer transistor TR1, a source follower transistor TR2, a selection transistor TR3, a reset transistor TR5, a photodiode switching transistor TR4, a capacitor connection transistor TR8, a power connection transistor TR9, the first node FD1 and the second node FD2, and a fourth node FD4 are provided in a first area (“REG1” of FIG. 2). The second photodiode SPD, a second transfer transistor TR7, a connection transistor TR6, a metal capacitor C, and the third node FD3 are provided in a second region (“REG2” of FIG. 2). The boundary between the first regions REG1 and REG2 may be defined by a front deep trench isolation (FDTI). The pixel circuit of the unit pixel UP is as illustrated in FIG. 3, and thus, redundant descriptions thereof will be omitted.

Referring to FIG. 6, the second node FD2 may be formed by a first contact FD2L, which is formed on the side of the first photodiode LPD, and a second contact FD2S, which is formed on the side of the second photodiode SPD. The first contact FD2L and the second contact FD2S may be connected through a metal wiring connection.

The second region REG2 includes the second photodiode SPD, the transfer transistor TG, which is connected to the second photodiode SPD, the second contact FD2S, which is connected to one end of a connection transistor SW1, and the third diffusion node FD3, which corresponds to a third floating diffusion node connected to the other end of the connection transistor SW1. The fourth node FD4 is connected to the third node FD3 through the metal capacitor C. According to an embodiment, a third contact corresponding to the fourth node FD4 may be provided outside the second region REG2.

In an example case in which each of the first regions REG1 has a hexagonal planar shape and each of the second regions REG2 has a square planar shape, unit pixels UP, each including one first region REG1 and one second region REG2, may be regularly arranged as illustrated in FIG. 7. Each first region REG1 and each second region REG2 may be separated by a deep trench insulating portion PDI. For example, the deep trench insulating portion PDI may be filled with an insulating material.

As mentioned earlier with reference to FIG. 6, the first contact FD2L and the fourth node FD4 may be provided in the first region REG1. The first contact FD2L may be provided adjacent to the second region REG1 belonging to the same unit pixel UP as the first region REG1. For example, the first contact FD2L may be provided near the second region REG1 belonging to the same unit pixel UP as the first region REG1. The first contact FD2L is electrically connected to the second contact FD2S through a metal wiring connection, thereby defining a single second node FD2. According to an embodiment, since the first contact FD2L and the second contact FD2S define a single second node FD2, the first contact may be referred to as (1-1)-th contact and the second contact may be referred to as (1-2)-th contact. According to an embodiment, a metal wiring connection may be a metal trace provided in a wiring layer of the image sensor. For example, the metal trace may provide a connection between the first contact FD2L and the second contact FD2S. For example, the metal trace may electrically connect the first contact FD2L and the second contact FD2S. For example, the metal trace may physically contact both the first contact FD2L and the second contact FD2S.

Also, as mentioned earlier with reference to FIG. 6, the second transfer transistor STG, the (1-2)-th contact FD2S, the third diffusion node FD3, and the connection transistor SW1 are provided in the second region REG2. The third diffusion node FD3 in the second region REG2 is connected to the fourth diffusion node FD4 through the metal capacitor C, draining the charge accumulated in the metal capacitor C to a first power supply line VDDA during an EIT in an example case in which the second transfer transistor TR7 is turned off and charge accumulates in the second photodiode SPD.

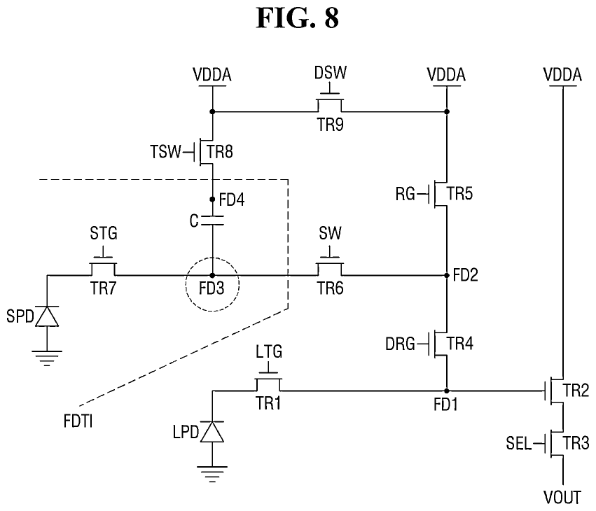

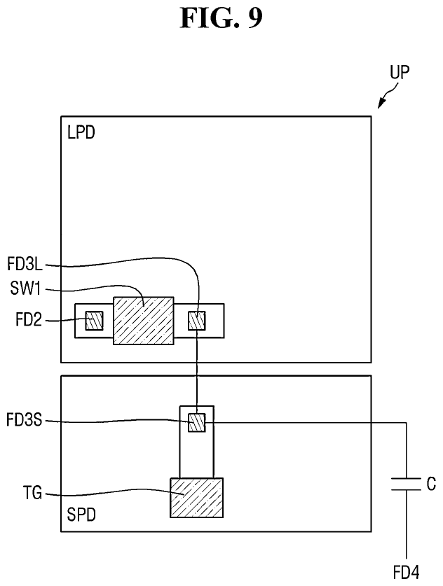

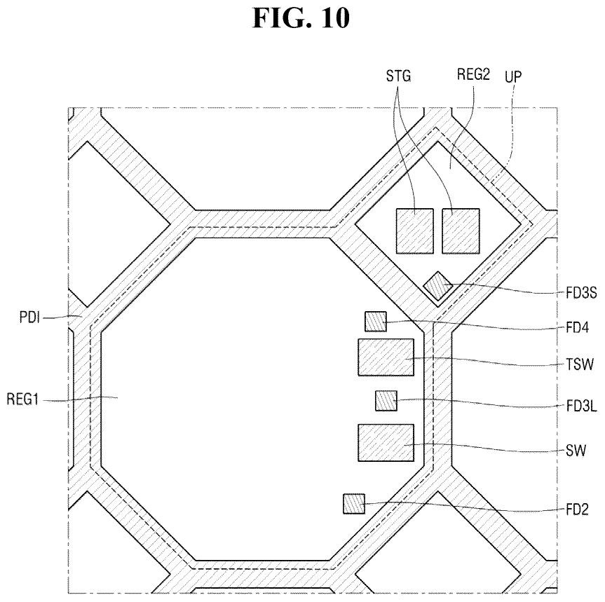

FIG. 8 is a circuit diagram of a unit pixel according to an embodiment, FIG. 9 is a diagram illustrating a layout of the unit pixel of FIG. 8, and FIG. 10 is a layout view of the unit pixel of FIG. 9.

In an embodiment, first and second photodiodes LPD and SPD of a unit pixel UP may be connected to a third node FD3. Consequently, the third node FD3 may be implemented with two contacts, i.e., (2-1)-th and (2-2)-th contacts FD3L and FD3S.

Referring to FIGS. 8 and 9, the first photodiode LPD, a first transfer transistor TR1, a source follower transistor TR2, a selection transistor TR3, a reset transistor TR5, a photodiode switching transistor TR4, a connection transistor TR6, a capacitor connection transistor TR8, a power connection transistor TR9, a first node FD1, a second node FD2, and a fourth node FD4 are provided in a first region (“REG1” of FIG. 2). The second photodiode SPD, a second transfer transistor TR7, a metal capacitor C, and the third node FD3 are provided in a second region (“REG2”) of FIG. 2. The boundary between the first and second regions REG1 and REG2 may be defined by an FDTI. The pixel circuit of the unit pixel UP of FIG. 8 is as illustrated in FIG. 3, and thus, redundant descriptions thereof will be omitted.

Referring to FIG. 9, the third node FD3 may be formed by the (2-1)-th contact FD3L, which is formed on the side of the first photodiode LPD, and the (2-2)-th contact FD3S, which is formed on the side of the second photodiode SPD, and may be connected through a metal wiring connection.

A connection transistor SW1, the first contact FD2, which is connected to one end of the connection transistor SW1, and the (2-1)-th contact FD3L, which is connected to the other end of the connection transistor SW1, are provided in the first region REG1. The (2-1)-th contact FD3L is electrically connected to the (2-2)-th contact FD3S through a metal wiring connection, thereby defining a single third node FD3. According to an embodiment, since the third contact FD3L and the fourth contact FD3S define a single third node FD3, the third contact may be referred to as (2-1)-th contact and the fourth contact may be referred to as (2-2)-th contact.

The second photodiode SPD, a transfer transistor TG, which is connected to the second photodiode SPD, and the (2-2)-th contact FD3S, which corresponds to a third floating diffusion node, are provided in the second region REG2. The fourth node FD4 is connected to the (2-2)-th contact FD3S through the metal capacitor C, but a third contact corresponding to the fourth node FD4 may be provided outside the second region REG2.

In an embodiment, if the first region REG1 has a hexagonal planar shape and the second region REG2 has a square planar shape, unit pixels UP each including one first region REG1 and one second region REG2 may be regularly arranged as illustrated in FIG. 10. Each first region REG1 and each second region REG2 may be separated by a deep trench insulating portion PDI, which is filled with an insulating material.

As mentioned earlier with reference to FIG. 9, the connection transistor SW1, a capacitor connection transistor TSW, the (2-1)-th contact FD3L, and the fourth diffusion node FD4 may be provided in the first region REG1. The (2-1)-th contact FD3L may be provided near the second region REG2 of the same unit pixel UP as the first region REG1. The (2-1)-th contact FD3L may be provided between a photodiode connection transistor SW and the capacitor connection transistor TSW.

Also, as mentioned earlier with reference to FIG. 9, the second region REG2 includes the second transfer transistor STG and the (2-2)-th contact FD3S. The (2-2)-th contact FD3S in the second region REG2 is connected to the fourth diffusion node FD4 through the metal capacitor C, draining the charge accumulated in the metal capacitor to a first power supply line VDDA during an EIT in an example case in which the transfer transistor TR7 is turned off and charge accumulates in the second photodiode SPD. As the photodiode connection transistor SW is provided in the first region REG1, rather than in the second region REG2, place and routing (PnR) advantages can be provided in terms of the design area for the second region REG2. For example, the second transfer transistor STG may be implemented as a dual transistor.

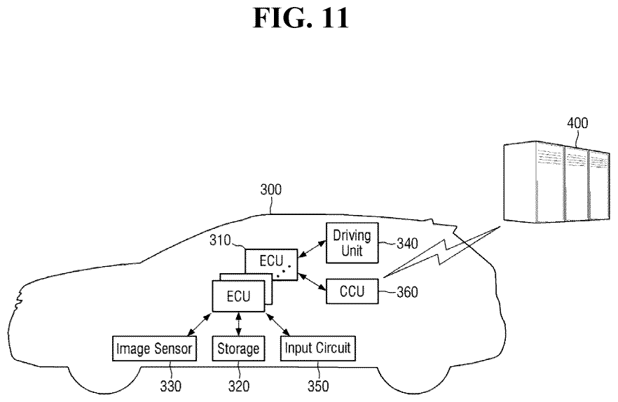

FIG. 11 is a schematic diagram of a vehicle including an image sensor according to an embodiment of the disclosure.

Referring to FIG. 11, a vehicle 300 may include a plurality of electronic control units (ECUs) 310 and a storage device 320.

Each of the ECUs 310 may be electrically, mechanically, or communicatively connected to at least one of a plurality of devices provided in the vehicle 300 and may control the operation of at least one connected device based on a function execution command.

Here, the plurality of devices may include an image sensor 330, which acquires images for performing at least one function, and a driving circuitry 340, which performs at least one function.

The image sensors according to the aforementioned embodiments may be applicable to the image sensor 330. The image sensor 330 may correspond to an automotive image sensor. Since the image sensor 330 has no leakage current from switch transistors for metal capacitors, the image sensor 330 can operate stronger against DSNU and can provide an improved SNR.

The driving circuitry 340 may include a fan and compressor of an air conditioning system, a fan of a ventilation system, an engine and motor of a power system, a motor of a steering system, a motor and valve of a braking system, and opening and closing devices for a door or tailgate.

The ECUs 310 may communicate with the image sensor 330 and the driving circuitry 340 using at least one of Ethernet communication, low voltage differential signaling (LVDS) communication, and local interconnect network (LIN) communication.

The ECUs 310 may determine the necessity of performing a particular function based on information acquired through the image sensor 330. In an example case in which it is determined that there is a need to perform the particular function, the ECUs 310 may perform the operation of the driving circuitry 340 performing the particular function, controlling the operational amount of the driving circuitry 340 based on the acquired information. Here, the ECUs 310 may store the acquired information in the storage device 320 or read and use information stored in the storage device 320. information stored in the storage device 320.

Additionally, the ECUs 310 may control the operation of the driving circuitry 340 performing a particular function based on a function execution command entered through an input circuit 350. The ECUs 310 may also control the operation of the driving circuitry 340 performing a particular function based on a setting amount corresponding to information entered through the input circuit 350.

Each of the ECUs 310 may control one function independently or in coordination with other ECUs 310.

For example, the ECU 310 of a collision avoidance system may be configured to output, through a speaker, a warning sound for a potential collision with an obstacle if the distance to the obstacle detected by a distance detection unit is within a reference range.

For example, the ECU 310 of an autonomous driving control system may receive navigation information, road image information, and obstacle distance information in coordination with the ECUs 310 of a vehicle terminal, an image acquisition unit, and the collision avoidance system, and perform autonomous driving by controlling the power system, the braking system, and the steering system using the received information.

A connectivity control unit (CCU) 360 may be electrically, mechanically, or communicatively connected to each of the ECUs 310 and communicates with each of the ECUs 310.

That is, the ECU 360 may directly communicate with the ECUs 310, provided within the vehicle, may communicate with an external server, and may communicate with an external device through an interface.

The CCU 360 may communicate with the ECUs 310 and may communicate with a server 400 using radio frequency (RF) communication with an antenna.

Moreover, the CCU 360 may wirelessly communicate with the server 400. Specifically, the CCU 360 may wirelessly communicate with the server 400 using various wireless communication methods such as Wireless Fidelity (Wi-Fi), Wireless Broadband (WiBro), Global System for Mobile Communication (GSM), Code Division Multiple Access (CDMA), Wideband Code Division Multiple Access (WCDMA), Universal Mobile Telecommunications System (UMTS), Time Division Multiple Access (TDMA), Long Term Evolution (LTE), etc.

The image sensor 330 is a type of optical sensor, and the technical concepts of the disclosure are also applicable to other types of sensors that use semiconductors to detect the amount of incident light, such as a fingerprint sensor and a distance measuring sensor.

Although embodiments of the disclosure have been described with reference to the attached drawings, it should be understood that the invention can be implemented in other specific forms without changing the technical spirit or essential features thereof. Thus, the embodiments described are to be considered in all respects as illustrative and not restrictive.

1. An image sensor comprising:
a pixel array comprising a plurality of unit pixels; and
a driving circuitry configured to drive the plurality of unit pixels,
wherein each of the plurality of unit pixels comprises:
a first region comprising a first photodiode, a first transfer transistor connected to the first photodiode, a first floating diffusion node connected to the first transfer transistor, and a first contact connected to a second floating diffusion node, and
a second region comprising a second photodiode, a second transfer transistor connected to the second photodiode, a second contact electrically connected to the first contact through a metal wiring connection, and a third contact provided to a third floating diffusion node connected to the second transfer transistor.

2. The image sensor of claim 1, wherein the second region further comprises a connection transistor provided between the second contact and the third contact.

3. The image sensor of claim 2, wherein each of the plurality of unit pixels further comprises:
a metal capacitor connected between the third contact and a fourth floating diffusion node, and
a capacitor connection transistor connected between the fourth floating diffusion node and a first power supply line.

4. The image sensor of claim 3, wherein the driving circuitry is configured to:
turn on the capacitor connection transistor during an effective integration time of the second photodiode, and
drain charge accumulated in the metal capacitor to the first power supply line according to a reset signal.

5. The image sensor of claim 1, wherein the first region further comprises:
a photodiode switching transistor comprising a first end connected to the second floating diffusion node, the photodiode switching transistor configured to turn on based on a photodiode switching control signal,
a reset transistor connected between the second floating diffusion node and a first power supply line, the reset transistor configured to turn on based on a reset signal,
a source-follower transistor comprising a gate connected to the first floating diffusion node and a first end connected to the first power supply line, and
a selection transistor connected between a second end of the source-follower transistor and an output signal line, the selection transistor configured to turn on based on a selection signal.

6. The image sensor of claim 5, wherein the first region further comprises a fourth contact connected to a fourth diffusion floating node.

7. An image sensor comprising:
a pixel array comprising a plurality of unit pixels; and
a driving circuitry configured to drive the plurality of unit pixels,
wherein each of the plurality of unit pixels comprises:
a first region comprising a first photodiode, a first transfer transistor connected to the first photodiode, a first floating diffusion node connected to the first transfer transistor, a first contact connected to a second floating diffusion node, and a second contact, and
a second region comprising a second photodiode, a second transfer transistor connected to the second photodiode, and a third contact connected to a third floating diffusion node together with the second contact.

8. The image sensor of claim 7, wherein the first region further comprises a connection transistor provided between the first contact and the second contact.

9. The image sensor of claim 8, wherein each of the plurality of unit pixels further comprises:
a metal capacitor connected between the third contact and a fourth floating diffusion node, and
a capacitor connection transistor connected between the fourth floating diffusion node and a first power supply line.

10. The image sensor of claim 9, wherein the driving circuitry is configured to:
turn on the capacitor connection transistor during an effective integration time of the second photodiode, and
drain charge accumulated in the third floating diffusion node and metal capacitor to the first power supply line according to a reset signal.

11. The image sensor of claim 8, wherein the first region further comprises:
a photodiode switching transistor comprising a first end connected to the second floating diffusion node, the photodiode switching transistor configured to turn on based on a photodiode switching control signal,
a reset transistor connected between the second floating diffusion node and a first power supply line, the reset transistor configured to turn on based on a reset signal,
a source-follower transistor comprising a gate connected to the first floating diffusion node and a first end connected to the first power supply line, and
a selection transistor connected between a second end of the source-follower transistor and an output signal line, the selection transistor configured to turn on based on a selection signal.

12. The image sensor of claim 11, wherein the first region further comprises a fourth contact connected to a fourth diffusion floating node.

13. The image sensor of claim 7, wherein the second transfer transistor is implemented as a dual-transfer transistor.

14. An image sensing device comprising:
a pixel array comprising a plurality of unit pixels; and
a driving circuitry configured to drive the plurality of unit pixels,
wherein each of the plurality of unit pixels comprises:
a first transfer transistor connected between a first photodiode and a first floating diffusion node,
a photodiode switching transistor connected between the first floating diffusion node and a second floating diffusion node, the photodiode switching transistor configured to turn on based on a photodiode switching control signal,
a second transfer transistor connected between a second photodiode and a third floating diffusion node,
a metal capacitor connected between the third floating diffusion node and a fourth floating diffusion node, and
a first connection transistor connected between the fourth floating diffusion node and a first power supply line, the first connection transistor configured to turn on based on a capacitor connection control signal.

15. The image sensing device of claim 14, wherein each of the plurality of unit pixels further comprises:
a source-follower transistor comprising a gate connected to the first floating diffusion node and a first end connected to the first power supply line,
a reset transistor connected between the second floating diffusion node and a first power supply line, the reset transistor configured to turn on based on a reset signal,
a selection transistor configured to turn on based on a selection signal and output an output signal corresponding to a signal at a second end of the source-follower transistor to an output signal line.

16. The image sensing device of claim 15, wherein the driving circuitry is configured to:
accumulate charge in the third floating diffusion node by turning on a second connection transistor and turning off the first connection transistor during an effective integration time of the second photodiode,
convert the charge accumulated in the third floating diffusion node and metal capacitor through the source-follower transistor by turning on the first connection transistor while maintaining the second connection transistor to be on, and
output the converted charge to an output signal line.

17. The image sensing device of claim 16, wherein the driving circuitry is configured to drain the charge accumulated in the third floating diffusion node and the metal capacitor to the first power supply line by turning on each of the first connection transistor and the reset transistor.

18. The image sensing device of claim 14, wherein each of the plurality of unit pixels further comprises:
a first region comprising the first photodiode and a first contact connected to the second floating diffusion node, and
a second region comprising the second photodiode, the second transfer transistor, a second contact electrically connected to the first contact through a first metal wiring connection, and a third contact connected to the third floating diffusion node.

19. The image sensing device of claim 18, wherein the second region further comprises a second connection transistor provided between the second contact and the third contact.

20. The image sensing device of claim 14, where each of the plurality of unit pixels further comprises:
a first region comprising the first photodiode, a first floating diffusion node connected to the first transfer transistor, a first contact connected to the second floating diffusion node, and a second contact connected to the third floating diffusion node, and
a second region comprising the second photodiode, the second transfer transistor connected to the second photodiode, and a third contact electrically connected to the second contact through a second metal wiring connection.

21. (canceled)

22. (canceled)
